(19) United States
(12) Patent Application Publication
(10) Pub. No.: US 2012/0126396 A1
(43) Pub. Date: May 24, 2012

(54) DIE DOWN DEVICE WITH THERMAL CONNECTOR

(75) Inventors: Sam Ziqun Zhao, Irvine, CA (US); Rezaur Rahman Khan, Rancho Santa Margarita, CA (US)

(73) Assignee: Broadcom Corporation, Irvine, CA (US)

(21) Appl. No.: 12/950,411

(22) Filed: Nov. 19, 2010

(51) Int. Cl. H01L 23/498; H01L 21/50

(52) U.S. Cl. 257/737; 438/107; 257/E23.068; 257/E21.499

(57) ABSTRACT

Methods and apparatuses for a die down device with a thermal connector are provided. In an embodiment, an integrated circuit (IC) device includes an IC die having opposing first and second surfaces, a thermal connector coupled to the first surface of the IC die, and a substrate. The second surface of the IC die is coupled to the substrate. The thermal connector is configured to be coupled to a circuit board.

### BACKGROUND

1. Field

The present invention generally relates to IC devices and IC device packages.

2. Background

Integrated circuit (IC) devices can be formed by mounting an IC die in or on a package that facilitates attachment to a printed circuit board (PCB). One such type of IC package is a ball grid array (BGA) package. BGA packages provide for relatively small footprints.

Existing BGA devices are subject to high thermal stresses that result from the heat given off during operation of the mounted IC die. The thermal stresses are often imposed on the IC device due to the heat generated by the IC die.

### BRIEF SUMMARY

Methods and apparatuses for a die down device with a thermal connector are provided. In one embodiment, an integrated circuit (IC) device includes an IC die having opposing first and second surfaces, a thermal connector coupled to the first surface of the IC die, and a substrate. The second surface of the IC die is coupled to the substrate. The thermal connector is configured to be coupled to a circuit board.

In another embodiment, a method of assembling an integrated circuit device includes coupling a thermal connector to a first surface of an IC die and coupling a second surface of the IC die to a substrate. The thermal connector is configured to be coupled to a circuit board.

Further features and advantages of the invention, as well as the structure and operation of various embodiments of the invention, are described in detail below with reference to the accompanying drawings.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIGS. 1 and 2 show diagrams of conventional integrated circuit (IC) devices.

FIG. 3 shows a diagram of a die-down IC device having a thermal connector.

FIG. 4 shows a diagram of the IC device shown in the embodiment of FIG. 3 being coupled to a printed circuit board.

FIG. 5 shows a diagram of an IC device having a thermal connector.

FIG. 6 shows a bottom view of the IC die and thermal connector shown in the embodiment of FIG. 5.

FIG. 7 shows a diagram of an IC device having a thermal connector.

FIG. 8 shows a bottom view of the IC die and thermal connector shown in the embodiment of FIG. 7.

FIG. 9 shows a diagram of an IC device having multiple thermal connectors.

FIG. 10 shows a bottom view of the IC die and thermal connectors shown in the embodiment of FIG. 9.

FIGS. 11-12 show diagrams of IC device having a thermal connector.

FIGS. 13-14 show diagrams of IC devices having a thermal connector including a coated material.

FIG. 15 shows a bottom view of the IC die and thermal connector shown in the embodiment of FIG. 14.

FIG. 16-17 show diagrams of IC devices having additional components.

FIG. 18 shows a top view of an antenna plane.

FIG. 19 shows a diagram of an IC device having multiple dies.

FIGS. 20-21 show diagrams of thermal lands.

FIG. 22 is a flowchart of an exemplary method of assembling an IC device.

FIG. 23 shows a diagram of an IC device having a thermal connector.

The present invention will be described with reference to the accompanying drawings. Generally, the drawing in which an element first appears is typically indicated by the leftmost digit(s) in the corresponding reference number.

### DETAILED DESCRIPTION OF THE INVENTION

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will fully reveal the general nature of the invention so that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

Furthermore, it should be understood that spatial descriptions (e.g., “above”, “below”, “left,” “right,” “up”, “down”, “top”, “bottom”, etc.) used herein are for purposes of illustration only, and that practical implementations of the structures described herein can be spatially arranged in any orientation or manner.

Overview

A ball grid array (BGA) package is used to package and interface an IC die with a printed circuit board (PCB). BGA packages may be used with any type of IC die, and are particularly useful for high speed ICs. In a BGA package, solder pads do not just surround the package periphery, as in chip carrier type packages, but cover the entire bottom package surface in an array configuration. BGA packages are also referred to as pad array carrier (PAC), pad array, land grid array, and pad-grid array packages.

Die-up and die-down BGA package configurations exist. In die-down flip-chip packages, the active surface of the IC die faces in a direction away from the PCB and solder bumps can be used to couple contact pads on a surface of the IC die to the substrate. In die-up flip-chip BGA packages, the IC die is mounted on a top surface of the substrate or interposer and the active surface of the IC die faces in a direction away from the PCB.

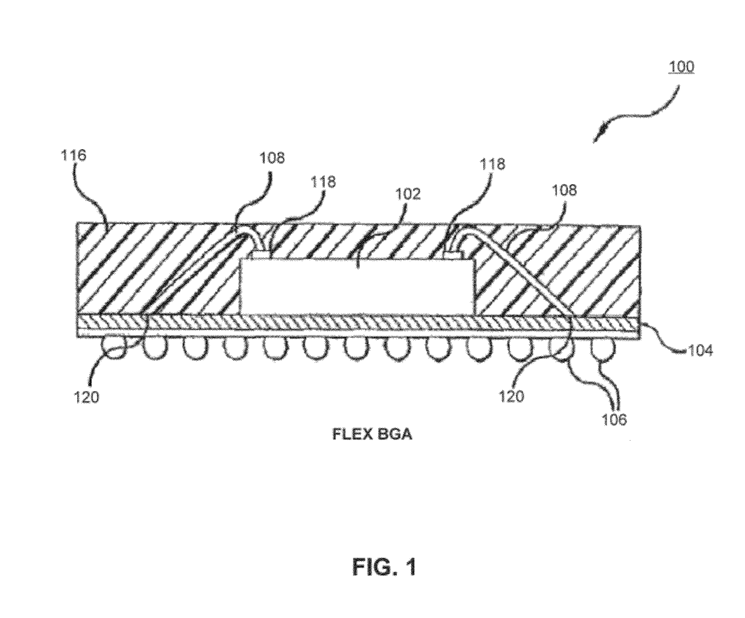

FIG. 1 shows a diagram of a conventional wire bond BGA device 100. BGA device 100 includes an IC die 102, a substrate 104, solder balls 106, and wire bonds 108.

Substrate 104 is generally made from one or more conductive layers bonded with a dielectric material. For instance, the dielectric material may be made from various substances, such as polyimide tape. The conductive layers are typically made from a metal, or combination of metals, such as copper and aluminum. Trace or routing patterns are made in the conductive layer material. In one embodiment, substrate 104 can be a single-layer, a two-layer, or additional layer substrate type. In a two-layer embodiment, the metal layers sandwich the dielectric layer, such as in a copper-Upilex-copper arrangement.

IC die 102 is attached to substrate 104, for example, by an epoxy. IC die 102 can be any type of semiconductor IC. One or more wire bonds 108 couple corresponding bond pads 118 on IC die 102 to contact points 120 on substrate 104. An encapsulate, mold compound, or epoxy 116 covers IC die 102 and wire bonds 108 for mechanical and environmental protection. Heat generated by IC die 102 can damage IC device 100. For example, the generated heat can lead to cracks in IC device 100.

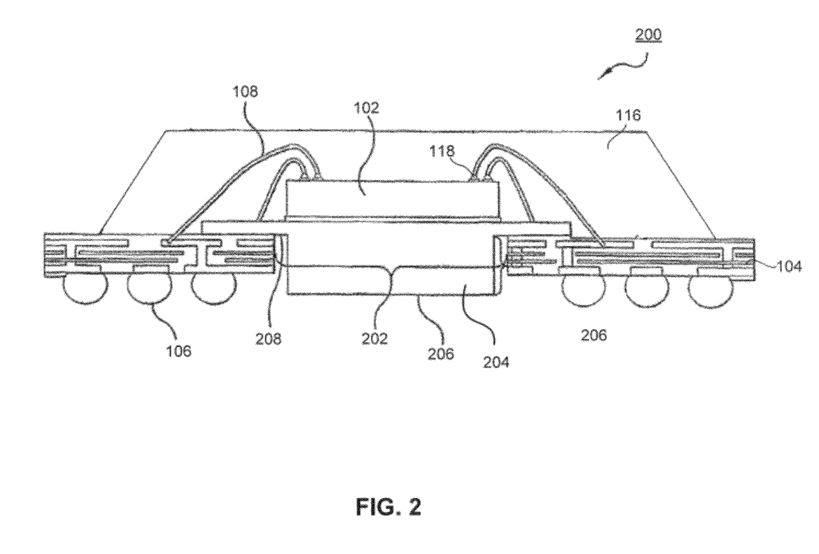

FIG. 2 shows a conventional IC device 200. IC device 200 includes IC die 102, substrate 104, solder balls 106, wire bonds 108, encapsulate 116, bond pads 118, and a stiffener 202.

As shown in FIG. 2, stiffener 202 is coupled to the top surface of substrate 104. Stiffener 202 includes a protruding portion 204 that protrudes through an opening 206 of substrate 104. In an embodiment, protruding portion 204 is configured to contact a printed circuit board (PCB) to which package 200 is mounted (not shown in FIG. 2).

Stiffener 202 serves to provide stiffening for IC package 200, especially in the embodiment in which substrate 104 is a flexible substrate. Furthermore, stiffener 202 can also spread heat from IC die 102. For example, stiffener 202 can spread heat from IC die 102 to the PCB to which package 200 is mounted. In doing so, stiffener 202 can effectively cool package 200.

Thus, in some BGA packages, a die is attached to the substrate of the package (e.g., using an adhesive), and signals of the die are interfaced with electrical features (e.g., bond fingers) of the substrate using wire bonds. In such a BGA package, wire bonds are connected between signal pads/terminals of the die and electrical features of the substrate. In another type of BGA package, which may be referred to as a “flip chip package,” a die may be attached to the substrate of the package in a “flip chip” orientation. In such a BGA package, solder bumps are foamed on the signal pads/terminals of the die, and the die is inverted (“flipped”) and attached to the substrate by reflowing the solder bumps so that they attach to corresponding pads on the surface of the substrate.

The dies in integrated circuit packages, such as BGA packages, typically generate a great amount of heat during operation. Thus, BGA packages are frequently configured to disperse the generated heat so that their operation is not adversely affected by the generated heat. For example, an external heat sink may be attached to a BGA package to disperse heat from the BGA package. External heat sinks are effective solutions to improving the thermal performance of a package. However, in the case of die-down flip chip BGA packages, the package geometry creates additional complexities in the mounting of such heat sinks. For example, phase array antennas are typically designed on a surface of the substrate. Mounting an external heat sink or heat sinking devices to this surface will interfere with antenna operation.

### Exemplary Embodiments

Although IC device 200 provides for heat spreading from IC die 202, IC device 200 can only be used in die up configurations. In embodiments described herein, IC devices are provided that allow for heat spreading in die down configurations. For example a thermal connector may be provided that couples an IC die to a PCB, thereby spreading heat from the IC die to the PCB.

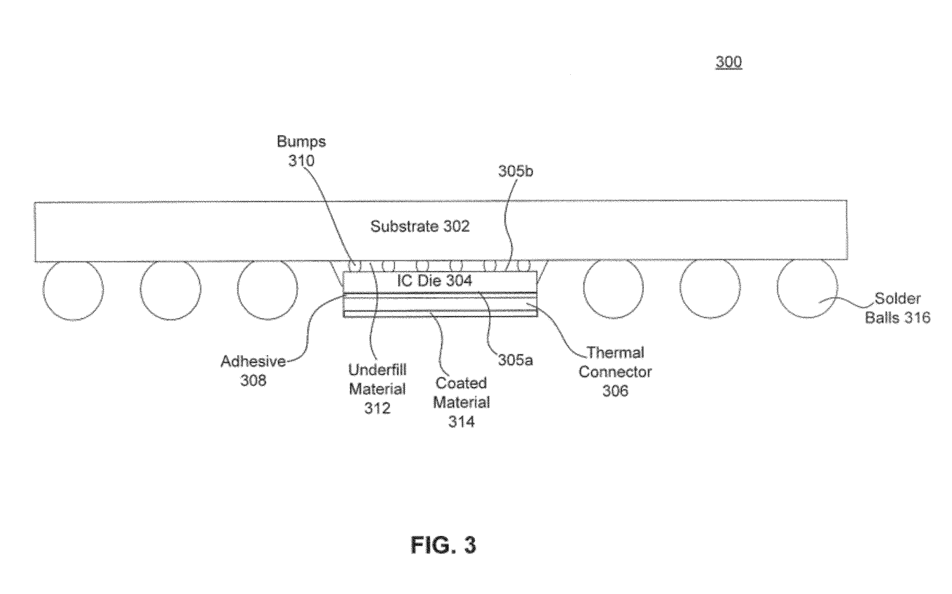

FIG. 3 shows a diagram of an IC device 300. IC package 300 includes a substrate 302, an IC die 304, a thermal connector 306, an adhesive 308, bumps 310, an underfill material 312, a coated material 314, and solder balls 316.

IC die 304 can be any one of a variety of types of IC dies. For example, IC die 304 can be an ASIC. In another embodiment, IC die 304 is a memory. Adhesive 308 couples thermal connector 306 to a first surface 305a of IC die 304. Adhesive 308 can be one of a variety of adhesives known to those skilled in the art. For example, adhesive 308 can be a thermally conductive adhesive, e.g., a thermally conductive epoxy. Thermal connector 306 will be described in greater detail below.

Substrate 302 is coupled to a second surface 305b of IC die 304 through bumps 310 and underfill material 312. Substrate 302 can be similar to substrate 104 described with reference to FIG. 1. For example, substrate 302 can have one or more metal layers that facilitate coupling between IC die 304 and solder balls 316.

Bumps 310 couple conductive regions on IC die 304 to conductive regions on substrate 302 and attach IC die 304 to substrate 302. Bumps 310 can be formed out of an electrically conductive material such as solder. Solder balls 316 are configured to couple substrate 302 to a PCB. Underfill material 312 physically fills the spaces in between IC die 304, solder bumps 310, and substrate 302. Underfill material 312 can be an encapsulation material, such as an epoxy.

Solder balls 316 are configured couple substrate 302 to a PCB. In alternate embodiments, other coupling elements can be used to couple substrate 302 to a PCB. For example, pins can be used to couple substrate 302 to a PCB.

Thermal connector 306 can be formed out a thermally conductive material. For example thermal connector 306 can be formed out of copper or silicon. In another embodiment, thermal connector 306 and adhesive 308 together can be implemented as a metal tape (e.g., a copper tape).

The thermal conductivity of air is approximately 0.026 W/° K/m. Compared to the thermal conductivity of silicon (in the approximate range of 130-150 W/m·K), air is not an effective conductor of heat from IC die 304. Furthermore, the thermal path between IC die 304 and a PCB through substrate 302 and solder balls 316 is a relatively long path (e.g., compared to the distance between first surface 305a and the PCB) and includes a variety of different materials, some of which do not have high thermal conductivities (e.g., the insulators included in substrate 302).

To provide an effective thermal path between IC die 304 and the PCB, thermal connector 306 is configured to couple IC die 304 to a PCB. In doing so, thermal connector 306 can conduct heat from IC die 304 to the PCB. The thermal conductivities of copper and silicon are approximately 390 W/m·K and 130 W/m·K, respectively. Thus, both silicon and copper have thermal conductivities that are approximately 1,000 times higher than air. Therefore, thermal connector 306 is much more effective at conducting heat away from IC die 304 than the air gap between IC die 304 and the PCB.

In a further embodiment, thermal connector 306 can be coated with a coating material 314. Coating material 314 can be used to enhance the coupling between thermal connector 306 and the PCB. For example, coating material 314 can facilitate the soldering of thermal connector 306 onto the PCB. Coating material 314 can be, for example, solder, tin, silver, or gold.

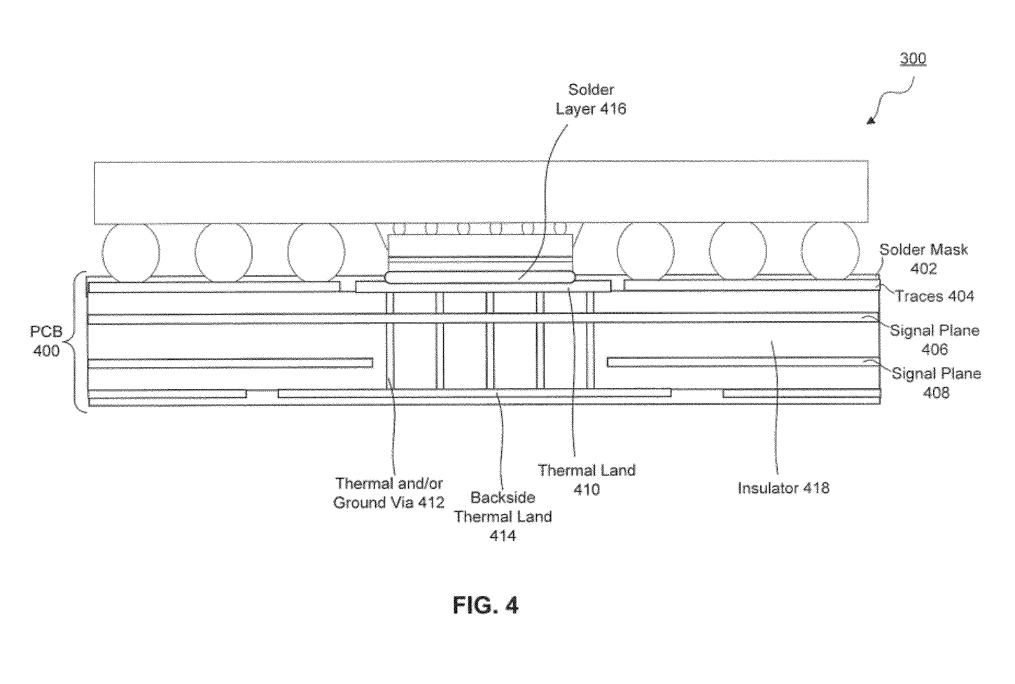

FIG. 4 shows a diagram of IC device 300 coupled to a PCB 400. PCB 400 includes a solder mask 402, traces 404, signal planes 406 and 408, a thermal land 410, thermal and/or ground vias 412, a backside thermal land 414, a solder layer 416, and an insulator 418.

Thermal connector 306 of IC device 300 (not numerically referenced in FIG. 4) is coupled to thermal land 410 through solder layer 416. In an embodiment, traces 404 and thermal land 410 are formed by etching a desired pattern in a copper layer. Thus, thermal land 410 can be formed using the same process used to form traces 404 and can be incorporated into an existing manufacturing process for PCB 400.

Signal planes 406 and 408 can be electrically conductive layers (e.g., copper layers) that are formed within insulator 418. One of signal planes 406 and 408 can be a ground plane. In another embodiment, neither of signal planes 406 and 408 is a ground plane.

Insulator 418 can be one of variety of different insulators used in printed circuit boards known to those skilled in the art. For example, insulator 418 can include a glass epoxy sheet such as FR-4. Although FIG. 4 shows insulator 418 as a homogenous material, in alternate embodiments, insulator 408 can be made up of different insulators (e.g., different dielectric layers). Moreover, instead of the four electrically conductive layers shown in FIG. 4, PCB 400 can have different numbers of conductive layers (e.g., two layers).

Thermal and/or ground vias 412 couple thermal land 410 to backside thermal land 414. Vias 412 can function as thermal vias that conduct heat away from thermal land 410. For example, vias 412 can be filled with a thermally conductive material (e.g., copper) to enhance the thermal coupling between thermal land 410 and backside thermal land 414. Vias 412 can also be configured to carry a ground potential to thermal land 410. For example, one or more of vias 412 can be coupled to signal plane 404, which can be coupled to a ground potential.

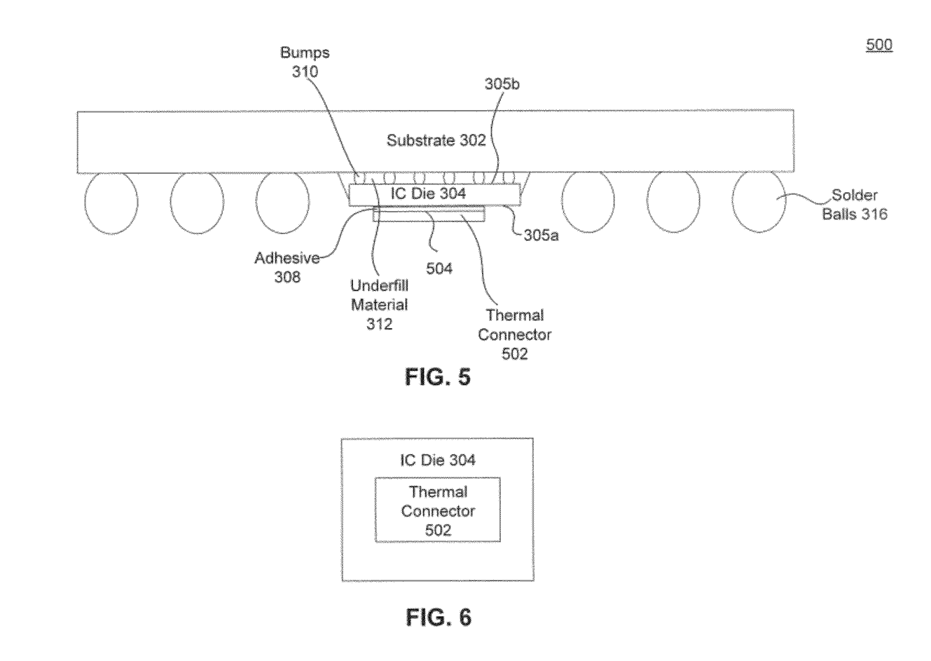

FIG. 5 shows a diagram of an IC device 500. IC device 500 is similar to IC device 300, shown in FIG. 3, except that thermal connector 306 of IC device 300 is replaced with thermal connector 502 in IC device 500. FIG. 6 shows a bottom view of thermal connector 502 and IC die 304, according to an embodiment of the present invention.

Thermal connector 502 has a surface 504 that is coupled to surface 305a of IC die 304. As shown in FIGS. 5 and 6, the area of surface 504 of thermal connector 502 is smaller than the area of surface 305a of IC die 304. In the embodiment of FIGS. 5 and 6, thermal connector 502 is located in the center of IC die 304. In alternate embodiments, thermal connector 502 can be located other locations relative to IC die 304.

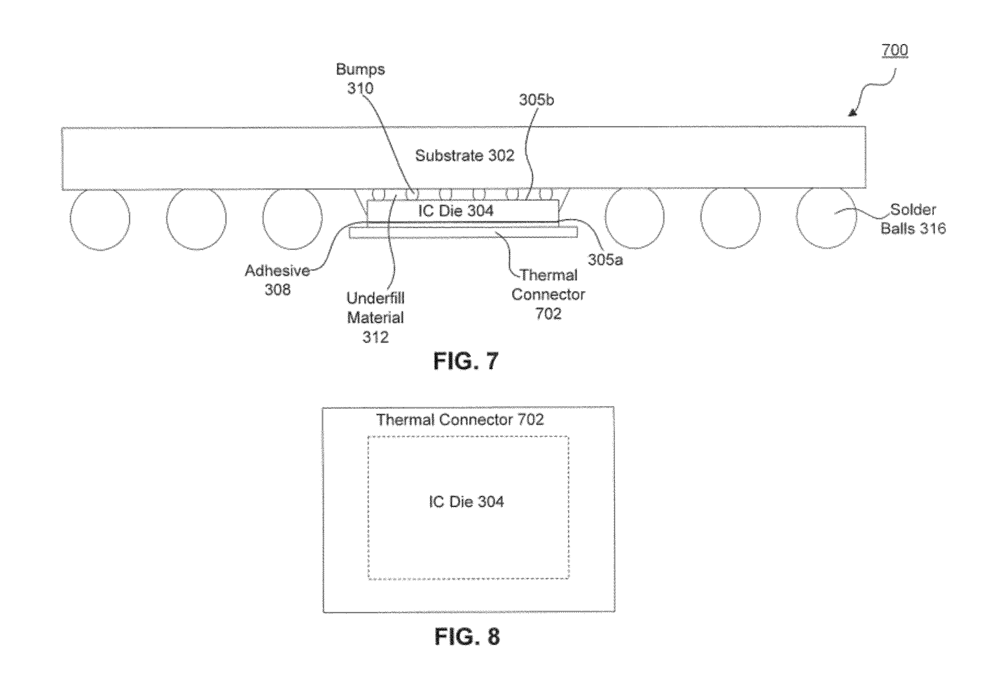

FIG. 7 shows a diagram of an IC device 700. IC device 700 is similar to IC device 300, shown in FIG. 3, except that thermal connector 306 of IC device 300 is replaced with thermal connector 702 in IC device 700. FIG. 8 shows a bottom view of thermal connector 702 and IC die 304. Thermal connector 702 has a surface 704 that is coupled to surface 305a of IC die 304. As shown in FIGS. 7 and 8, the area of surface 704 of thermal connector 502 is greater than the area of surface 305a of IC die 304.

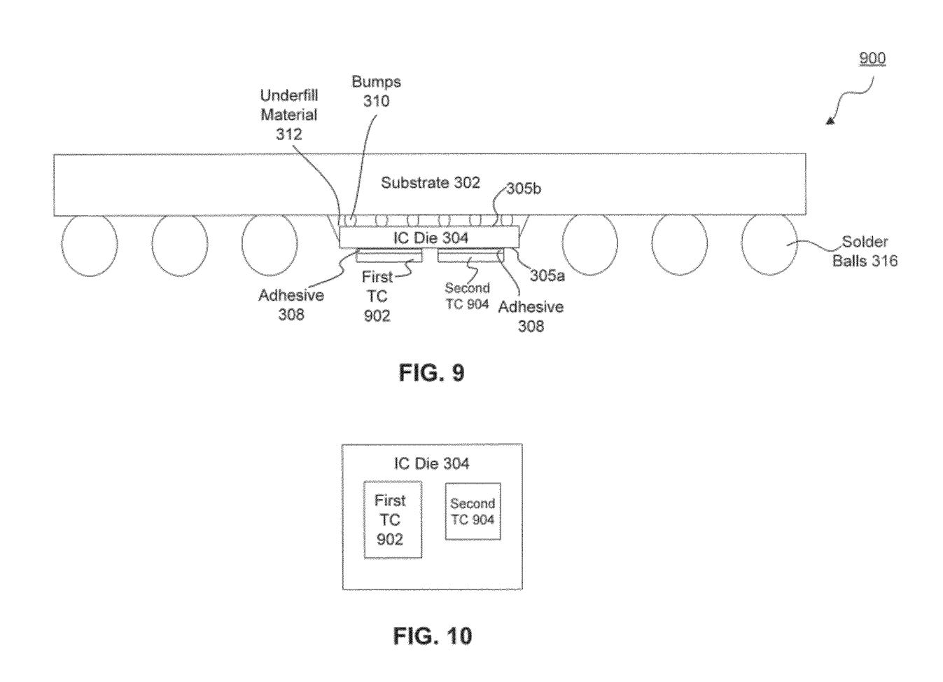

FIG. 9 shows an IC device 900. IC device 900 is similar to IC device, shown in FIG. 3, except that thermal connector 306 of IC device 300 is replaced with first and second thermal connectors 902 and 904 in IC device 900. FIG. 10 shows a bottom view of IC die 304 and first and second thermal connectors 902 and 904.

In one embodiment, first and second thermal connectors 902 and 904 can be located at hotspots of IC die 304. For example, IC die 304 can be analyzed to determine the location of one or more hotspots, i.e., location(s) on first surface 305a of IC die 304 that are relatively warmer during operation compared with the rest of first surface 305. For example, the analysis can include mapping functional blocks of die 304 to determine the location of the one or more hotspots. In another embodiment, the analysis includes performing a thermal analysis/measurement of the die during operation to determine the locations of the one or more hotspots.

By locating first and second thermal connectors 902 and 904 at hotspots of IC die 304, heat can be conducted from the hotspots, while conducting less heat from the cooler spots/areas (because thermal connectors are not coupled to the cooler spots/areas). In this manner, a thermal signature of IC die 304 surface can be made more uniform (cooling the hotspots to be closer in temperature to the cooler spots/areas).

### Molded Underfill Embodiments

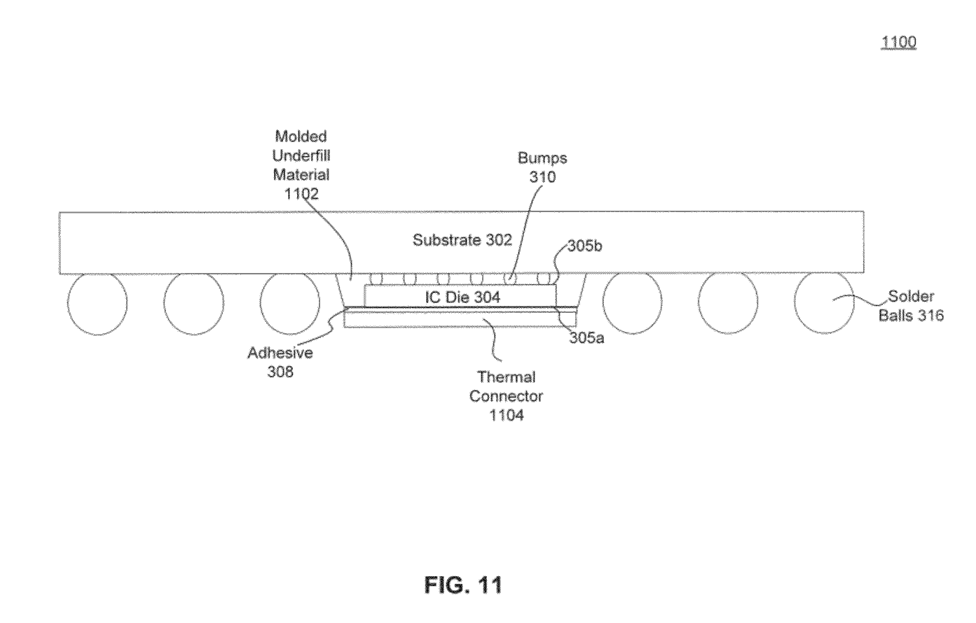

FIG. 11 shows an IC device 1100. IC device 1100 is similar to IC device 300, described with reference to FIG. 3, except that underfill material 312 and thermal connector 306 of IC device 300 are replaced with molded underfill material 1102 and thermal connector 1104, respectively.

In IC device 300, underfill material 312 can be a capillary underfill material that fills the gap between IC die 304 and substrate 302. In IC device 1100, on the other hand, underfill material 1102 can be a molded underfill material that is forced under IC die 304 and couples IC die 304. For example, the shape of molded underfill material 1102 can be set using a mold cavity or chase. Specifically, the mold cavity or chase can be filled with the underfill material, thus setting the shape of the underfill material based on the shape of the mold cavity or chase.

As shown in FIG. 11, underfill material 1102 encapsulates IC die 304 such that first surface 305a is left exposed. First surface 305a of IC die 304 is coupled to thermal connector 1104 via adhesive 308.

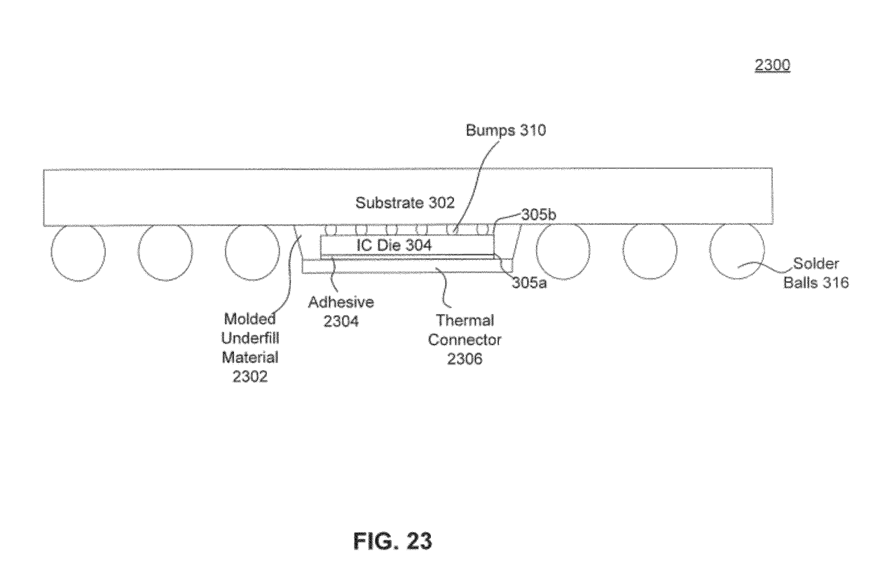

FIG. 23 shows an IC device 2300. IC device 2300 is similar to IC device 1100, described with reference to FIG. 11, except that molded underfill material 1102, adhesive 308, and thermal connector 1102 are replaced with molded underfill material 2302, adhesive 2304, and thermal connector 2306, respectively. Specifically, in contrast to the embodiment of FIG. 11, thermal connector 2306 is in contact with both adhesive 2304 and molded underfill material 2302.

In an embodiment, the devices shown in FIGS. 11 and 23 can be formed using different assembly steps. For example, IC device 1100 can be assembled by attaching IC die 304 to substrate 302, filling in the spaces between IC die 304 and substrate 302 with molded underfill material 1102, and attaching thermal connector 1104 to IC die 304 using adhesive 308. In contrast, IC device 2300 can be assembled by attaching IC die 304 to substrate 302, attaching thermal connector 2306 to IC die 304 using adhesive 2304, and filling in the spaces between IC die 304 and substrate 302 with molded underfill material 2302.

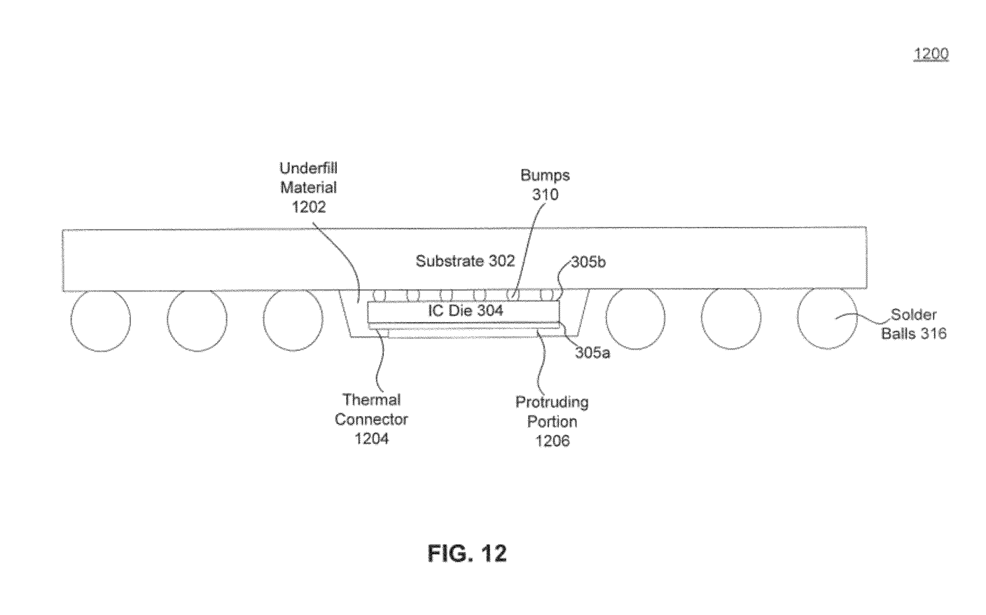

FIG. 12 shows an IC device 1200. IC device 1200 is similar to IC device 300, shown in FIG. 3, except that underfill material 312 and thermal connector 306 in IC device 300 are replaced with molded underfill material 1202 and thermal connector 1204. Moreover, adhesive 308 is omitted in IC device 1200.

Molded underfill material 1202 encapsulates both IC die 304 and thermal connector 1204. In doing so, underfill material 1202 effectively locks thermal connector 1204 on first surface 305a of IC die 304. That is, underfill material 1202 presses thermal connector 1204 against first surface 305a of IC die 304. Thus, an adhesive may not be needed to couple thermal connector 1204 to first surface 305a of IC die 304. In alternate embodiments, IC device 1200 can include an adhesive that further strengthens the coupling between thermal connector 1204 and IC die 304.

Underfill material 1202 can be molded using a mold chase or cavity. Thermal connector 1204 can be placed inside of the mold chase or cavity before the underfill material is applied. Once the underfill material is injected into the mold chase or cavity, thermal connector 1204 can be locked into place.

As shown in FIG. 12, thermal connector 1204 includes a protruding portion 1206. Protruding portion 1206 can be configured to fit into a thermal land formed in a PCB.

### Coated Thermal Connector Embodiments

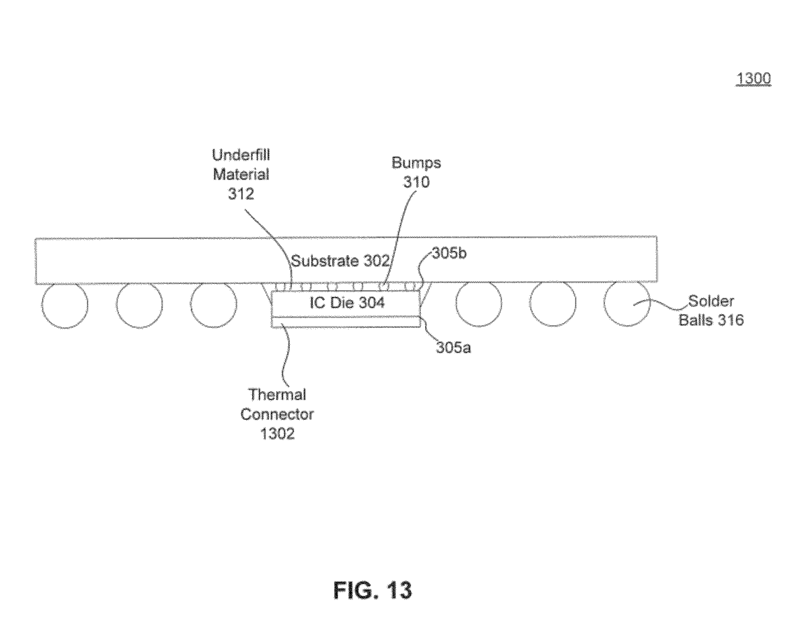

FIG. 13 shows an IC device 1300, according to an embodiment of the present invention. IC device 1300 is substantially similar to IC device 300, shown in FIG. 3, except that thermal connector 306 in IC device 300 is replaced with thermal connector 1302 in IC device 1300 and adhesive 308 is omitted from IC device 1300.

Thermal connector 1302 can be created using a wafer backside metallization process, as would be understood by those skilled in the art based on the description herein. The wafer (which includes multiple IC dies) can be processed to create thermal connector 1302 before the assembly process for IC device 1300 begins. Thus, thermal connector 1302 can be provided without adding steps to the package assembly process for IC device 1300.

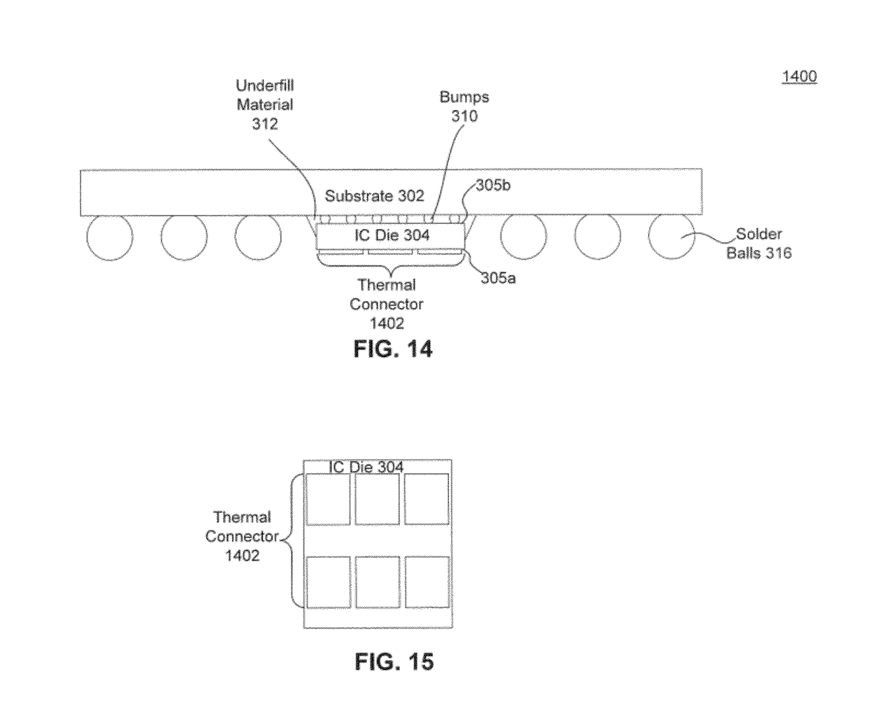

FIG. 14 shows an IC device 1400. IC device 1400 is substantially similar to IC device 1300, shown in FIG. 13, except that thermal connector 1302 is replaced with thermal connector 1402. FIG. 15 shows a bottom view of IC die 304 and thermal connector 1402.

Thermal connector 1402 is a patterned thermal connector in which some regions of first surface 305a of IC die 304 are left exposed, while other regions of first surface 305a are covered by thermal connector 1402. One or more regions of first surface 305a that can be covered by thermal connector 1402 can be hotspots of IC die 304.

Thermal connector 1402 can be created by coating a wafer with a thermally conductive material and etching the coated material to form a desired pattern (e.g., the pattern shown in FIGS. 14 and 15). Alternatively, areas that are to remain exposed can be masked before the coating to create the desired patterns.

Thermal connectors 1302 and 1402 can be formed out of one of a variety of different thermally conductive materials that can be coated to the surface of a wafer. For example, thermal connectors 1302 and 1402 can be formed out of gold, aluminum, tin, or silver-tin, or aluminum-tin alloys.

### Embodiments Including Multiple Components Coupled to the Substrate

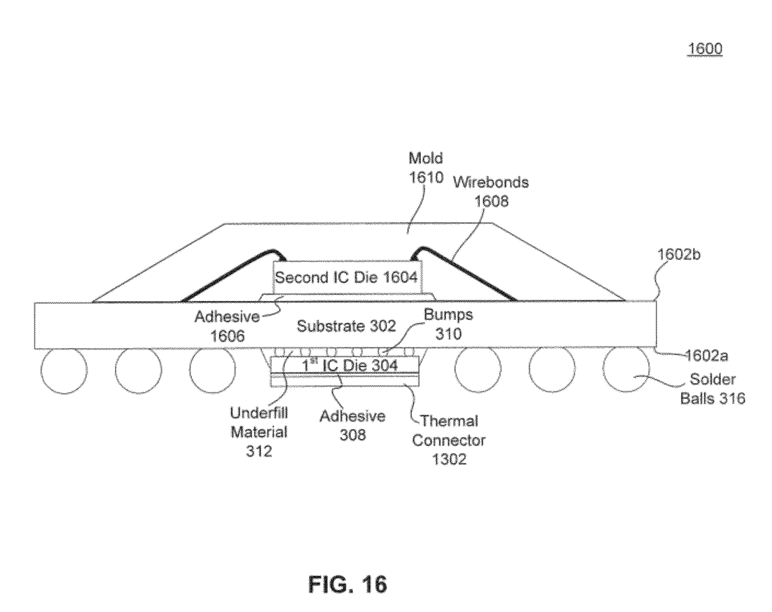

FIG. 16 shows an IC device 1600. IC device 1600 includes substrate 302, first IC die 304, thermal connector 306, adhesive 308, bumps 1310, solder balls, 316, a second die 1604, an adhesive 1606, wirebonds 1608, and a mold compound 1610.

As shown in FIG. 16, substrate 302 has first and second surfaces 1602a and 1602b. First and second IC dies 304 and 1604 are coupled to first and second surfaces 1602a and 1602b of substrate 302. As shown in FIG. 16, second IC die 1604 is coupled to second surface 1602a of substrate 302 via adhesive 1606. Adhesive 1606 can be substantially similar to adhesive 308.

Second IC die 1604 is mounted onto substrate 302 in a die up configuration. Electrical connections between second IC die 1604 and substrate 302 are provided by wirebonds 1608. Mold compound 1610 encapsulates second IC die 1604 and wirebonds 1608.

First IC die 304 can be coupled to second IC die 1604 through substrate 302. First IC die 304 can be an ASIC and second IC die 1604 can be a corresponding memory coupled to first IC die 304. Including an ASIC and a corresponding memory in the same device can optimize memory to ASIC interconnections and reduce the length of the connections between the two elements. Moreover, when an ASIC and a memory are included in separate packages, the resulting system can suffer from performance variations both due to the ASIC and memory being assembled by different parties and due to variations caused by the interconnections between the ASIC and memory (e.g., the interconnections on a PCB). By including the ASIC and memory in the same package, each of these types of performance variation can be reduced or eliminated. In other embodiments, second IC die 1604 can also be other types devices, e.g., RF devices.

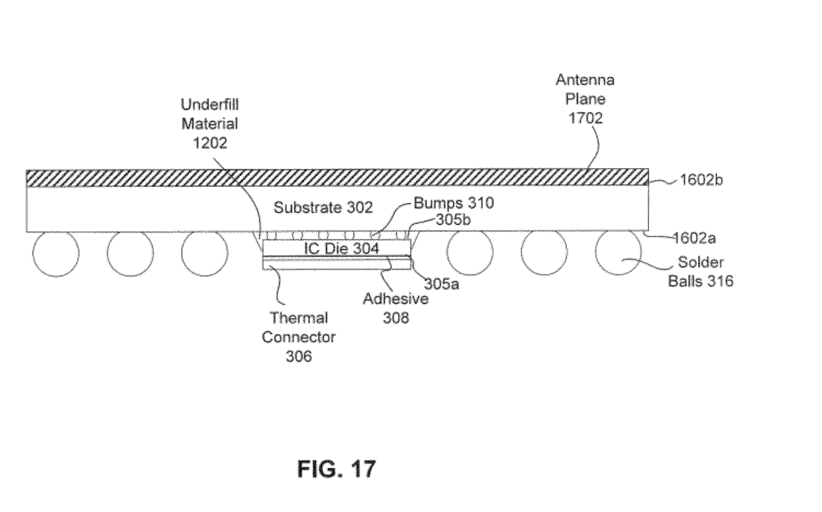

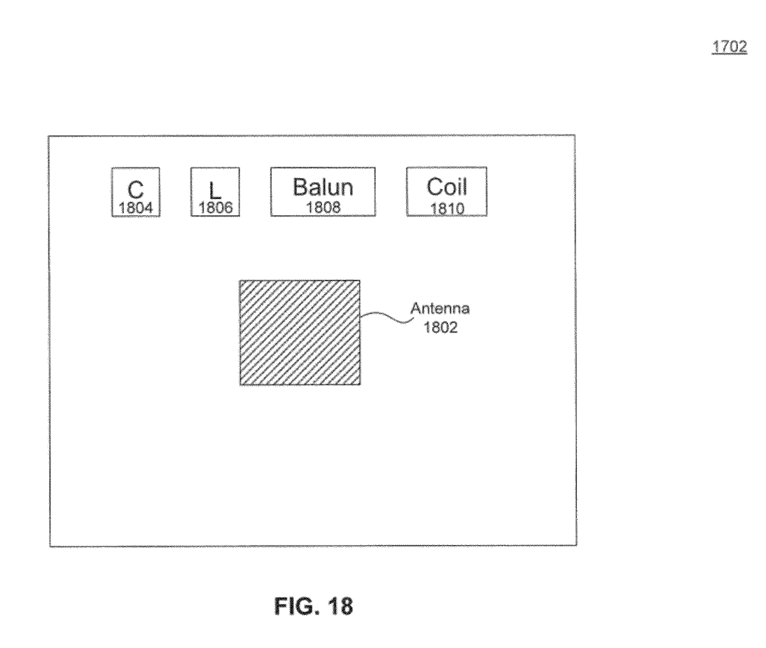

FIG. 17 shows a diagram of an IC package 1700. IC device 1700 includes substrate 302, IC die 304, thermal connector 306, adhesive 308, bumps 1310, solder balls, 316, and an antenna plane 1702. FIG. 18 shows a top view of antenna plane 1702.

Antenna plane 1702 is coupled to second surface 1602b of substrate 302. As shown in FIG. 18, antenna plane 1702 can include a variety of components. For example, antenna plane 1702 can include a variety of components, such as an antenna 1802, a capacitor 1804, an inductor 1806, a balun 1808, and a coil 1810. In alternate embodiments, antenna plane 1702 can include a subset of components 1802-1810. In other embodiments, antenna plane 1702 can include other passive devices, as would be appreciated by those skilled in the art based on the description herein. IC die 304 can be coupled to one or more of components 1802-1810 through vias formed in substrate 302 and traces formed on the antenna plane 1702. For example, IC die 304 can be coupled to antenna 1802 so that IC die 304 can communicate with other IC devices wirelessly.

Antenna 1802 is shown as a patch antenna in FIG. 18. In alternate embodiments, antenna 1802 can be different types of antennas as would be appreciated by those skilled in the art based on the description herein.

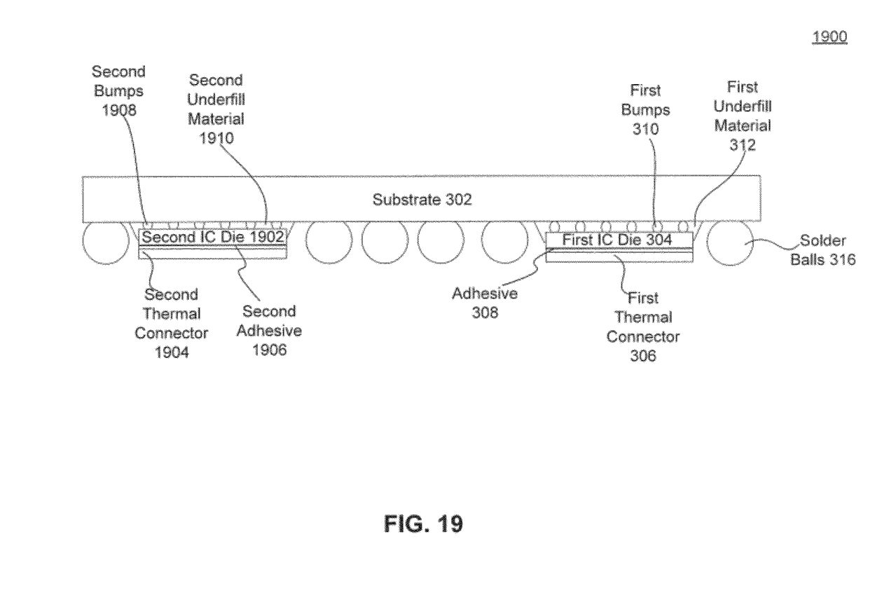

FIG. 19 shows an IC device 1900. IC device 1900 includes substrate 302, first IC die 304, first thermal connector 306, first adhesive 308, first bumps 1310, first underfill material 312, solder balls 316, a second IC die 1902, a second thermal connector 1904, a second adhesive 1906, second bumps 1908, and a second underfill material 1910.

Second IC die 190, second thermal connector 1904, second adhesive 1906, second bumps 1908, and second underfill material 1910 can be substantially similar to first IC die 304, first thermal connector 306, first adhesive 308, first bumps 1310, and first underfill material 312. Thus, in IC device 1900, multiple IC dies can be coupled to first surface 1602a of substrate 302. In the embodiment shown in FIG. 19, two IC dies are coupled to first surface 1602a of substrate 302. However, as would be appreciated by those skilled in the art based on the description herein, additional dies can also be coupled to first surface 1602a in a similar manner as for first and second dies 304 and 1902.

Including multiple IC dies in a single device can reduce the size of the overall component (e.g., because packaging is provided for the dies as a whole rather than each individual die). For example, in the embodiment in which an IC device is to be included in a mobile device, such as a cellular phone, by including multiple IC dies in single device (e.g., as shown in FIG. 19), the overall size of the mobile device can be reduced or additional functionality can be added without increasing the size of the device.

### Thermal Land Embodiments

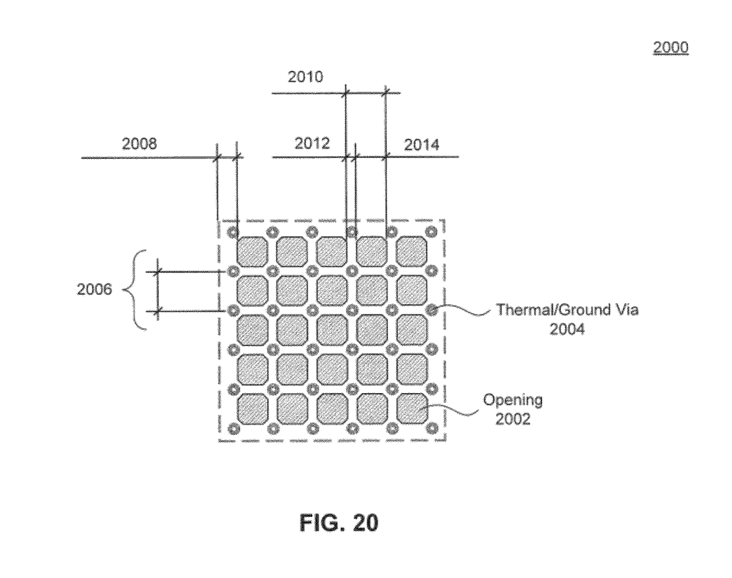

As described above, a thermal land is an area on a PCB that receives a thermal connector. The thermal land has thermally conductive material that conducts heat away from the thermal connector. FIG. 20 shows a diagram of a thermal land 2000. Thermal land 2000 includes openings 2002 and thermal/ground vias 2004. Openings 2002 can be openings in a solder mask that expose regions underneath the solder mask. For example, openings 2002 can expose thermally conductive regions that are formed out of a thermally conductive material, such as copper.

Thermal/ground vias 2004 can be similar to thermal/ground vias 412 described with reference to FIG. 4. As shown in FIG. 20, thermal/ground vias 2004 can be partially filled. In an embodiment, thermal/ground vias 2004 can be filled with a material that is thermally and electrically material such as copper. In a further embodiment, thermal/ground vias 2004 can be filled with a material having a thickness of approximately 15-20 μm (e.g., where the diameter of thermal/ground vias is approximately 225 μm).

A distance 2006 between the center of adjacent thermal/ground vias 2004 can be approximately 1 mm. A distance 2008 between the center of an outer one of thermal/ground vias 2004 and the outer edge of thermal land 2000 can be approximately 100 μm. A distance 2010 between edges of adjacent thermal/ground vias 2004 can be approximately 1 mm. A distance 2014 between opposite edges of adjacent thermal/ground vias 2004 can be approximately 0.9 mm. As noted above, a diameter 2012 of thermal/ground vias 2004 can be approximately 225 μm.

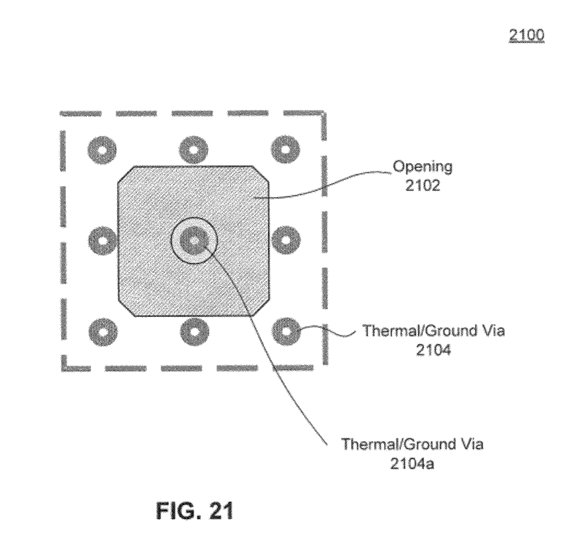

FIG. 21 shows a diagram of a thermal land 2100. Thermal land 2100 can be used for relatively smaller thermal connectors (e.g., whereas thermal land 2000, shown in FIG. 20, can be used for relatively larger thermal connectors). Thermal land 2100 includes an opening 2102 and thermal/ground vias 2104. As shown in FIG. 21, opening 2102 surrounds a thermal/ground via 2104a. As shown in FIG. 21, thermal/ground via 2104a is capped. Solder mask, epoxy, or other suitable materials can be used to cap thermal/ground via 2104a. Capping thermal/ground via 2104a can prevent materials (e.g., solder) from entering thermal/ground via 2104a during a reflow surface mount assembly process.

Exemplary Methods of Assembly

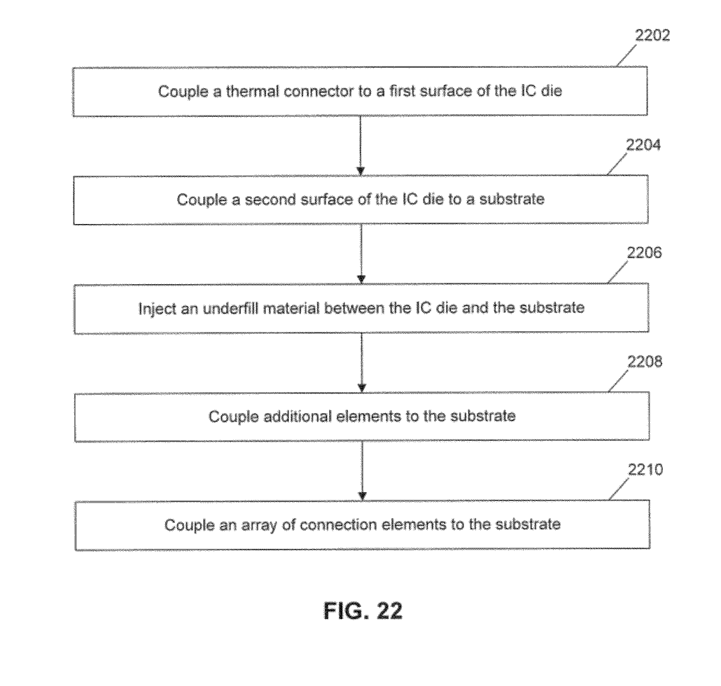

FIG. 22 is a flowchart of an exemplary method 2200 of assembly an IC device. Other structural and operational embodiments will be apparent to persons skilled in the relevant art(s) based on the following discussion. The steps shown in FIG. 22 do not have to occur in the order shown. The steps of FIG. 22 are described in detail below.

In step 2202, a thermal connector is coupled to a first surface of an IC die. For example, in FIG. 3, thermal connector 306 is coupled to first surface 305a of IC die 304. Thermal connector can be coupled to the first surfaces of the IC die using an adhesive as in, e.g., the embodiments shown in FIGS. 3, 5, 7, 9, 11, 16, 17, and 19. In another embodiment, the thermal connector can be coupled to the first surface of the IC die by locking it into place using a molded underfill material as in, e.g., the embodiment shown in FIG. 12. In still another embodiment, the thermal connector can be coupled to the first surface of the IC die by coating the first surface of the IC die with a thermally conductive material as in, e.g., the embodiments of FIGS. 13 and 14.

The thermal connector can be coupled to the first surface of the IC die before or after wafer singulation. Before wafer singulation, the thermal connectors can be coupled as a group to the first surface of each IC die in the wafer. After singulation, the thermal connectors can be coupled to the first surface of each IC die individually.

In step 2204, the second surface of the IC die is coupled to a substrate. For example, in FIG. 3, second surface 305b of IC die 304 is coupled to substrate 302 through bumps 310.

In step 2206, an underfill material is injected between the IC die and the substrate. For example, in FIG. 3, underfill material 312 can be injected to fill the spaces between substrate 302 and IC die 304. In an embodiment, underfill material 312 can protect solder bumps 310.

In optional step 2208, additional elements are coupled to the substrate. For example, in the embodiments of FIGS. 16-19, an additional component, such as an additional IC die, an antenna, a capacitor, an inductor, and/or a coil can be coupled to the substrate.

In step 2210, an array of connection elements can be coupled to the substrate. For example, in FIG. 3, solder balls 316 can be coupled to substrate 302. Solder balls 316 can be used to couple substrate 302 to a PCB.

Once the IC device has been manufactured, the IC device can be coupled to a PCB. For example, the IC device can be mounted on a PCB that includes a thermal land for receiving the thermal connector.

As noted above, the steps of flowchart 2200 do not have to occur in the order shown. For example, step 2204 can occur before step 2202 (e.g., the second surface of the IC die can be coupled to the substrate before the thermal connector is coupled to the first surface of the IC die). In a further embodiment, the step 2206 can occur before step 2202 (e.g., the underfill material can be injected between the substrate and the IC die before the thermal connector is coupled the first surface of the IC die).

### CONCLUSION

While various embodiments of the present invention have been described above, it should be understood that they have been presented by way of example only, and not limitation. It will be apparent to persons skilled in the relevant art that various changes in fowl and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A die-down integrated circuit (IC) device, comprising:
an IC die having opposing first and second surfaces;
a thermal connector coupled to the first surface of the IC die; and
a substrate, wherein the second surface of the IC die is coupled to a surface of the substrate,
wherein the thermal connector is configured to be coupled to a circuit board.

2. The die-down IC package of claim 1, further comprising:
an adhesive that couples the thermal connector to the first surface of the IC die.

3. The die-down IC package of claim 1, wherein the thermal connector has a surface coupled to the first surface of the IC die, and wherein an area of the surface of the thermal connector is larger than an area of the first surface of the IC die.

4. The die-down IC package of claim 1, wherein the thermal connector is a first thermal connector, the die-down IC package further comprising:
a second thermal connector coupled to the first surface of the IC die.

5. The die-down IC package of claim 1, further comprising:
bumps that couple the first surface of the IC die to the substrate.

6. The die-down IC package of claim 1, further comprising:
an underfill material between the first surface of the IC die and the substrate.

7. The die-down IC package of claim 6, wherein the underfill material encapsulates the IC die, leaving the first surface of the IC die exposed.

8. The die-down IC package of claim 6, wherein the underfill material locks the thermal connector on the first surface of the IC die.

9. The die-down IC package of claim 1, further comprising a material coating the thermal connector to facilitate coupling the thermal connector to the circuit board.

10. The die-down IC package of claim 1, wherein the thermal connector comprises a thermally conductive material coated on the first surface of the IC die.

11. The die-down IC package of claim 1, wherein the thermal connector is located at a hotspot of the IC die.

12. The die-down IC package of claim 1, wherein the substrate has a second surface that opposes the first surface of the substrate, the die-down IC package further comprising:
a passive element coupled to the second surface of the substrate.

13. The die-down IC package of claim 1, further comprising:
a second IC die coupled to the substrate.

14. The die-down IC package of claim 13, wherein the substrate has a second surface that opposes the first surface of the substrate and wherein the second IC die is coupled to the first surface of the substrate or the second surface of the substrate.

15. The die-down IC package of claim 1, wherein thermal connector comprises a protruding portion and wherein the protruding portion is configured to be coupled to the circuit board.

16. A method of assembling a die-down integrated circuit device, comprising:
(i) coupling a thermal connector to a first surface of an IC die, wherein the thermal connector is configured to be coupled to a circuit board; and
(ii) coupling a second surface of the IC die to a surface of a substrate.

17. The method of claim 16, wherein step (i) comprises:
coupling the thermal connector to the IC die using an adhesive.

18. The method of claim 16, further comprising:
(iii) coupling a second thermal connector to the first surface of the IC die.

19. The method of claim 16, wherein step (ii) comprises:
coupling bumps on the first surface of the IC die to the surface of the substrate.

20. The method of claim 16, further comprising:
(iii) molding an underfill material that between the first surface of the IC die and the surface of the substrate.

21. The method of claim 20, wherein the underfill material locks the thermal connector on the first surface of the IC die.

22. The method of claim 16, further comprising:
(iii) coating the thermal connector with a material that facilitates coupling the thermal connector to the circuit board.

23. The method of claim 16, wherein step (i) comprises:
coating the first surface of the IC die with a thermally conductive material.

24. The method of claim 16, wherein step (i) comprises:
coupling the thermal connector to a hotspot of the IC die.

25. The method of claim 16, wherein the substrate has a second surface that opposes the first surface of the substrate, the method further comprising:
(iii) coupling a passive element to the second surface of the substrate.

26. The method of claim 16, further comprising:
(iii) coupling a second IC die to the substrate.

27. The method of claim 26, wherein the substrate has a second surface that opposes the first surface of the substrate and wherein step (iii) comprises:
coupling the second IC die to the to the first surface of the substrate or the second surface of the substrate.
